(19) United States
(12) Patent Application Publication
(10) Pub. No.: US 2026/0005036 A1
(43) Pub. Date: Jan. 1, 2026

(54) LOW THERMAL BUDGET LASER ANNEALING

(71) Applicant: Applied Materials, Inc., Santa Clara, CA (US)

(72) Inventors: Shashank SHARMA, Fremont, CA (US); Nicolas Louis BREIL, San Jose, CA (US); Liu JIANG, Santa Clara, CA (US)

(21) Appl. No.: 18/755,537

(22) Filed: Jun. 26, 2024

(51) Int. Cl. H01L 21/324; H01L 21/67; H01L 21/687; H01L 21/768; H01L 23/532

(52) U.S. Cl. CPC H01L 21/324; H01L 21/67115; H01L 21/68764; H01L 21/76802; H01L 21/76871; H01L 21/76877; H01L 23/53257

(57) ABSTRACT

The embodiments herein provide thermal processing apparatus. The thermal processing apparatus includes a radiation module configured to generate a line of radiation for an annealing process, a substrate support configured to receive a substrate thereon, and a translation mechanism. The substrate support includes one or more channels configured to flow a working fluid therethrough. The working fluid is configured to enable a bottom surface of the substrate disposed upon the substrate support to be cooled to a temperature of about 200° C. to about −200° C. during the annealing process. The translation mechanism is configured to translate the substrate support and the line of radiation relative to one another.

### BACKGROUND

### Field

Embodiments of the present disclosure generally relate to semiconductor devices and methods for manufacturing semiconductor devices. More particularly, the disclosure relates to low thermal budget laser annealing.

### Description of the Related Art

The integrated circuit (IC) market is continually demanding greater memory capacity, faster switching speeds, and smaller feature sizes. One of the major steps the industry has taken to address these demands is to change from batch processing multiple substrates, such as silicon wafer, in large furnaces to single substrate processing in small reaction chambers.

Generally, there are four basic operations performed in such batch processing fabrication, namely layering, patterning, doping, and heat treatments. Many of these operations require heating the substrate to high temperatures so that various chemical and physical reactions can take place.

Heat treatments are operations in which the substrate is simply heated and cooled to achieve specific results. During heat treatment, no additional material is added to or removed from the substrate. Heat treatments, such as rapid thermal processing or annealing, typically require providing a relatively large amount of thermal energy (high temperatures) to the substrate in a short amount of time, and thereafter rapidly cooling the substrate to terminate the thermal process. The amount of thermal energy transferred the substrate during such processing is known as the thermal budget. The thermal budget of a material is a function of the temperature and the duration of the process. A low thermal budget material is desired in IC manufacturing, which can only be provided at high temperatures if the time of the process is very short.

Thus, there is a need in the art for improved heat treatments methods and apparatus to reduce the thermal budget expenditure of low thermal budget materials in an IC.

### SUMMARY

The present disclosure generally relate to semiconductor devices and methods for manufacturing semiconductor devices. More particularly, the disclosure relates to low thermal budget laser annealing.

In one embodiment, a thermal processing apparatus is disclosed. The thermal processing apparatus includes a radiation module configured to generate a line of radiation for an annealing process, a substrate support configured to receive a substrate thereon, and a translation mechanism. The substrate support includes one or more channels configured to flow a working fluid therethrough. The working fluid is configured to enable a bottom surface of the substrate disposed upon the substrate support to be cooled to a temperature of about 200° C. to about −200° C. during the annealing process. The translation mechanism is configured to translate the substrate support and the line of radiation relative to one another.

In another embodiment, a device is disclosed. The device includes a substrate, a backside isolation layer disposed over the substrate, a backside contact formed through the backside isolation layer and the substrate, a device voltage in contact with the backside isolation layer and the backside contact, a series voltage in contact with the backside isolation layer and the backside contact, a frontside signal line disposed between a bottom surface of the device and the device voltage and the series voltage, and a dopant disposed on or implanted in the device voltage and the series voltage. The dopant is an activated dopant configured to promote a formation of a metal to semiconductor contact. The dopant is activated using an annealing process. The device is disposed on a substrate support during the annealing process. The substrate support is configured to cool a bottom surface of the device to a temperature of about 200° C. to about −200° C. during the annealing process.

In yet another embodiment, a method of processing a device is disclosed. The method includes etching a backside isolation layer of a partial device to form a plurality of trenches to expose a device voltage (Vdd) and a series voltage (Vss). A dopant is deposited material on the Vdd and the Vss. A partial device is positioned in a thermal processing apparatus. The partial device is disposed on a stage of the thermal processing apparatus. A dopant activation process is performed to activate the dopant material. A bottom surface of the partial device is cooled using the stage. The bottom surface of the partial device is at a temperature of about 200° C. to about −200° C. during the dopant activation. A backside contact is deposited in the trenches.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, and may admit to other equally effective embodiments.

FIG. 1A is a schematic side view of an apparatus for thermally processing a substrate, according to embodiments.

FIG. 1B is a schematic top view of the substrate and stage, according to embodiments.

FIG. 2 is a schematic side view of an apparatus having an optical guide and a prism for thermally processing a substrate, according to embodiments.

FIG. 3 illustrates the controller, according to embodiments.

FIG. 4 illustrates a device, according to embodiments.

FIG. 5 illustrates a flow diagram of a method of forming a device, according to embodiments.

FIG. 6A-6D illustrate schematic, cross-section views of a portion of the substrate during the method of FIG. 5, according to embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure generally relate to semiconductor devices and methods for manufacturing semiconductor devices. More particularly, the disclosure relates to low thermal budget laser annealing.

Many of the details, dimensions, angles and other features shown in the figures are merely illustrative of particular embodiments. Accordingly, other embodiments can have other details, components, dimensions, angles and features without departing from the spirit or scope of the present disclosure. In addition, further embodiments of the disclosure can be practiced without several of the details described below.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals (e.g., tungsten), metal nitrides (e.g., TiN), metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface.

In addition to film processing directly on the surface of the substrate itself, in the present disclosure, any of the processing steps disclosed may also be performed on an intermediate layer formed on the substrate as disclosed in more detail below, and the term “substrate surface” is intended to include such intermediate layer as the context indicates. Thus, for example, where a film/layer or partial film/layer has been deposited onto a substrate surface, the exposed surface of the newly deposited film/layer becomes the substrate surface.

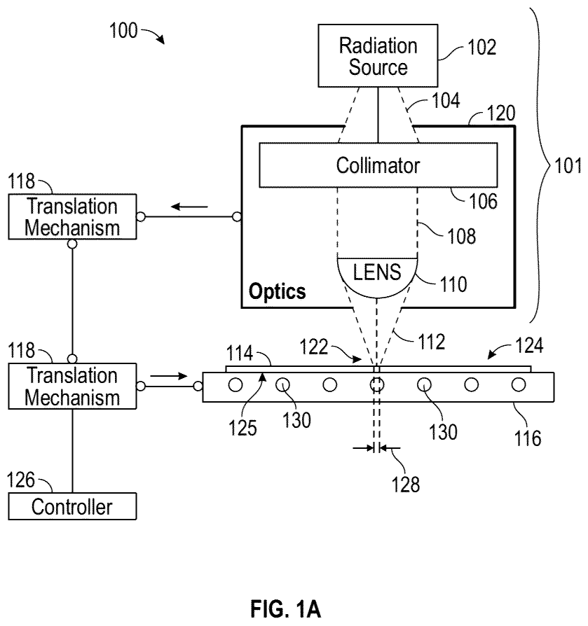

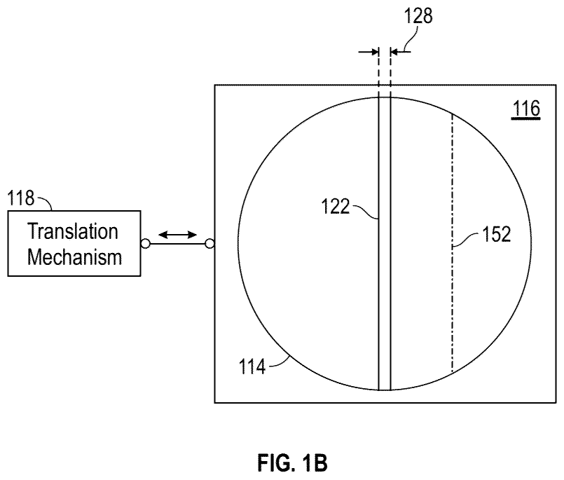

FIG. 1A is a schematic side view of an apparatus 100 for thermally processing a substrate 114. Thermally processing a substrate means conducting any thermal process. Exemplary embodiments of such thermal processes include thermal annealing of substrates or thermal processes used in chemical vapor deposition (CVD).

The apparatus 100 comprises a radiation module 101, a stage 116 (e.g., a substrate support) configured to receive the substrate 114 thereon, and a translation mechanism 118. The radiation module 101 includes a radiation source 102 and optics 120. The optics 120 include a collimator 106 and a lens 110. The optics 120 are disposed between the radiation source 102 and the stage 116. The substrate 114 is any suitable substrate, such as a single crystal silicon substrate, silicon on insulator (SOI), silicon germanium or alloys thereof, glass or quartz substrate with a silicon layer thereon, or other materials used for manufacturing thin film transistors (TFTs).

The radiation source 102 is capable of exposing the substrate 114 to rapid high temperature anneal pulses. The rapid high temperature anneal pulses are dynamic surface anneal (DSA) pulses, such that laser pulses are applied to the surface of the substrate 114 using radiation source 102. The laser pulses may be performed in a laser annealing chamber, such as a DSA chamber. The DSA process may be a scanning DSA process and may be performed in a scanning DSA chamber. The DSA process may be a millisecond anneal process, which includes heating the substrate to a temperature in a range from about 300° C. to about 1,300° C., or in a range from about 1,000° C. to about 1,300° C., or in a range from about 1,000° C. to about 1,200° C., or about 1,150° C. to about 1,200° C. for a period of about 0.05 milliseconds to about 5 milliseconds, about 0.1 milliseconds to about 2 milliseconds, about 0.2 millisecond to about 1 millisecond, or about 0.5 millisecond to about 1 millisecond.

Furthermore, as the radiation needs to be absorbed at or near an upper surface 124 of the substrate, the radiation has a wavelength within the range at which the substrate absorbs radiation. In some embodiments, the radiation has a wavelength from about 190 nm to about 950 nm, such as about 810 nm. Alternatively, a high power radiation laser source operation in or near the UV range may be used. Wavelengths produced by such radiation laser sources are strongly absorbed by most otherwise reflective materials.

The radiation source 102 comprises multiple laser diode(s), each of which produces uniform and spatially coherent light at the same wavelength. The power of the laser diode(s) is in the range of about 0.5 KW to about 50 KW, such as approximately 5 kW. The laser diode(s) provide about 40 watts to about 480 watts of continuous wave power per laser diode module.

The focusing optics 120 include one or more collimators 106 to collimate radiation 104 from the radiation source 102 into a substantially parallel collimated beam. This collimated radiation 108 is then focused by at least one lens 110 into a line of radiation 122 at the upper surface 124 of the substrates 114. The lens 110 is any suitable lens, or series of lenses, capable of focusing the collimated radiation 108 into a line. In some embodiments, the lens 110 is a cylindrical lens. In other embodiments, the lens 110 may be one or more concave lenses, convex lenses, plane mirrors, concave mirrors, convex mirrors, refractive lenses, diffractive lenses, Fresnel lenses, gradient index lenses, or the like.

The stage 116 is any platform or chuck capable of securely holding the substrate 114 during translation. In some embodiments, the stage 116 incudes a means for grasping the substrate, such as a frictional, gravitational, mechanical, or electrical system. A suitable means for grasping include mechanical clamps, electrostatic or vacuum chucks, or the like.

The stage 116 includes one or more channels 130 through which a working fluid may flow. The working fluid allows for a bottom surface 125 of the substrate 114 disposed upon the stage 116 to be cooled, by conduction, to a lower temperature during the thermal processing (e.g., the DSA processing). The working fluid may include any suitable gas or liquid, including, but not limited to, ammonia (NH₃), brines, hydrocarbons, chlorofluorocarbons, hydrochlorofluorocarbons, hydrofluorocarbons, hydrofluro-olefins, carbon dioxide (CO₂), oxygen (O), argon (Ar), fluorine (F), air, nitrogen (N), neon (Ne), hydrogen (H), helium (He), or combinations thereof. By adjusting the composition, or magnitude, of the working fluid flowing through the one or more channels 130 of the stage 116, the stage 116 may be between about 200° C. to about −200° C. For example, the stage 116 temperature is about 200° C. to about 100° C., such as about 150° C. For example, the stage 116 temperature is about 100° C. to about 0° C., such as 25° C. For example, the stage 116 temperature is about −10° C. to about −30° C. For example, the stage 116 temperature is about 15° C. to about −25° C. For example, the stage 116 temperature is about −80° C. to about to about −120° C., such as about −100° C. The bottom surface 125 of the substrate 114 disposed upon the stage 116 may be cooled, and maintained, by the stage 116 to a temperature of less than about 400° C., such as about −100° C. to about 300° C., such as about 175° C.

The apparatus 100 includes a translation mechanism 118 configured to translate the stage 116 and the line of radiation 122 relative to one another. In one embodiment, the translation mechanism 118 is coupled to the stage 116 to move the stage 116 relative to the radiation source 102 and/or the focusing optics 120. In other embodiments, the translation mechanism is coupled to both the radiation source 102 and the focusing optics 120 to move the radiation source 102 and/or the focusing optics 120 relative to the stage 116. In yet another embodiment, the translation mechanism moves the radiation source 102, the focusing optics 120, and the stage 116. Any suitable translation mechanism may be used, such as a conveyor system, rack and pinion system, or the like.

The translation mechanism 118 is coupled to a controller 126 to control the scan speed at which the stage 116 and the line of radiation 122 move relative to one another. In addition, the translation of the stage 116 and the line of radiation 122 relative to one another is along a path perpendicular to the line of radiation 122 and parallel to the upper surface 124 of the substrate 114. In one embodiments, the translation mechanism 118 moves at a constant speed. The speed is about 50 mm/s to about 50 cm/sec, such as about 2 cm/s, for a line of about 3 microns to about 500 microns, such as about 35 microns. In another embodiment, the translation of the stage 116 and the line of radiation 122 relative to on another is not along a path perpendicular to the line of radiation 122.

FIG. 1B is a schematic top view of the substrate 114 and stage 116. In one embodiment, the substrate 114 is a circular substrate with a diameter of about 200 mm to about 300 mm, and a thickness of about 700 microns to about 800 microns, such as about 750 microns. The line of radiation 122 extends about 5 mm to about 350 mm across the substrate 114. The line of radiation 122 also preferably has a width of between 3 microns and about 500 microns. The line of radiation 122 has a length that extends across the entire diameter or width of the substrate and has a width 128 of approximately 35 microns. The width is measured at half of the maximum intensity of the radiation (otherwise known as the Full Width Half Max (FWHM)). The length of the line is longer than its width. The line of radiation linearly traverses the substrate 114, such that the line of radiation 122 is perpendicular to the direction of the movement, e.g., the line of radiation 122 remains parallel to a fixed line or chord 152 of the substrate 114 that is perpendicular to the direction of the movement at all time.

The line of radiation is scanned across the upper surface 124 of the substrate 114. A power density at the line of radiation is from about 10 KW/cm² to about 200 kW/cm², such as about 60 KW/cm². The line of radiation enables heating of the upper surface 124 of the substrate 114 to about 800° C. to about 1300° C., such as about 850° C.

The stage 116 enables an increase in the temperature gradient along the depth of the substrate 114. In one example, the temperature gradient from an upper surface 124 of the substrate 114 to the temperature at the bottom surface 125 of the substrate 114 is about 300° C. to about 1400° C., such as about 700° C. to about 1400° C., such as about 500° C. to about 1400° C., such as about 300° C. to about 1000° C. The temperature gradient, for example, encompasses the temperature at the upper surface 124 of the substrate 114 (e.g., about 500° C. to about 1200° C.) to the temperature at the bottom surface 125 of the substrate 114 (e.g., about 200° C. to about −200° C.). The increase in the temperature gradient along the depth of the substrate 114 reduces the thermal budget expenditure of a structure deposited closer to the bottom surface 125 of the substrate 114. For example, frontside signal lines including a copper material that are deposited using back end of line (BEOL) processes experience a reduced expenditure of their thermal budget due to the increased temperature gradient along the depth of the substrate 114, as the frontside signal lines will only experience temperature between about 200° C. to about −200° C. Meanwhile, the upper surface 124 of the substrate 114 may still be processed at the higher temperatures (e.g., about 500° C. to about 1200° C.) required to perform dopant activation, film densification, annealing, or other applications.

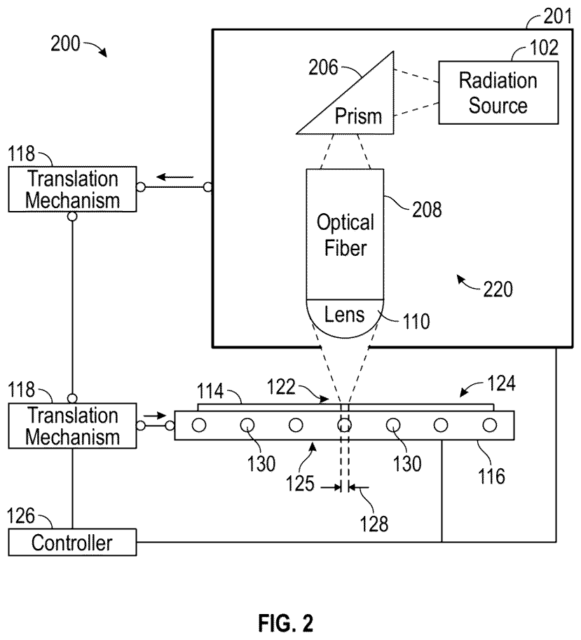

FIG. 2 is a schematic side view of an apparatus 200 having an optical fiber 208 and a prism 206 for thermally processing a substrate 114. The apparatus 200 includes a radiation module 201, a stage 116 (e.g., a substrate support) configured to receive the substrate 114 thereon, and a translation mechanism 118. The radiation module 201 includes a radiation source 102 and optics 220. The optics 220 are disposed between the radiation source 102 and the stage 116. The optics 220 include a lens 110 and one or more radiation guides, such as the optical fiber 208 and the prism 206. Other radiation guides, such as a waveguide, a mirror, or a diffuser may also be utilized. Radiation from the radiation source 102 is directed at one or more prisms 206, which redirects the radiation towards one or more optical fibers 208. Radiation is transmitted through the optical fibers 208 towards the lens 110, where it is focused into a line of radiation 122.

In other examples, different combinations of optics 120 or optics 220 may be used to transmit and focus the radiation from the radiation source 102 into a line of radiation. Also, a linear array of laser diodes could be used as the radiation source 102. Any suitable means for producing a uniform radiation distribution, such as a radiation diffuser, may be used in conjunction with the radiation source 102.

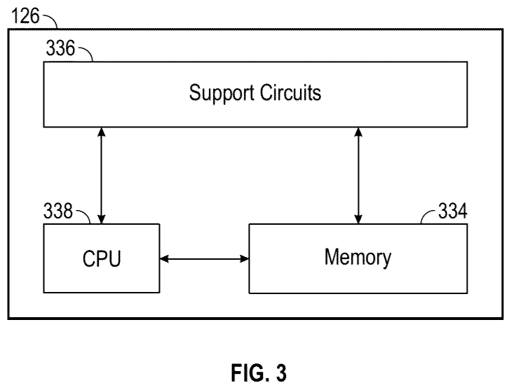

FIG. 3 illustrates the controller 126. The controller 126 is configured to receive data or input from the apparatus 100 or the apparatus 200. The apparatus 100 or apparatus 200 includes a plurality of sensors. The controller includes a memory 334, support circuits 336, and a central processing unit (CPU) 338 (e.g., a processor). The controller 126 controls various components of the apparatus 100 or the apparatus 200 directly, or via other computers and/or controllers.

The controller 126 is any form of general purpose computer processor that is used in an industrial setting for controlling the apparatus 100 or apparatus 200. The memory 334, or non-transitory computer readable medium, is one or more of a readily available memory such as random access memory (RAM), dynamic random access memory (DRAM), static RAM (SRAM), and synchronous dynamic RAM (SDRAM) (e.g., DDR1, DDR2, DDR3, DDRL3, LPDDR3, DDR4, LPDDR4, and the like)), read only memory (ROM), floppy disk, hard disk, flash drive, or any other form of digital storage, local or remote. The support circuits 336 of the controller 126 are coupled to the CPU 338 for supporting the CPU 338. The support circuits 336 include cache, power supplies, clock circuits, input/output circuitry and subsystems, and the like. Operational parameters and operations are stored in the memory 334 as a software routine that is executed or invoked to turn the controller 126 into a specific purpose controller to control the operations of the apparatus 100 or apparatus 200. The controller 126 is configured to conduct any of the operations described herein. The instructions stored on the memory 334, when executed, cause one or more of the operations (such as operations of the method 500) described herein to be conducted in relation to the apparatus 100 or apparatus 200.

The various operations described herein can be conducted automatically using the controller 126, or can be conducted automatically or manually with certain operations conducted by a user.

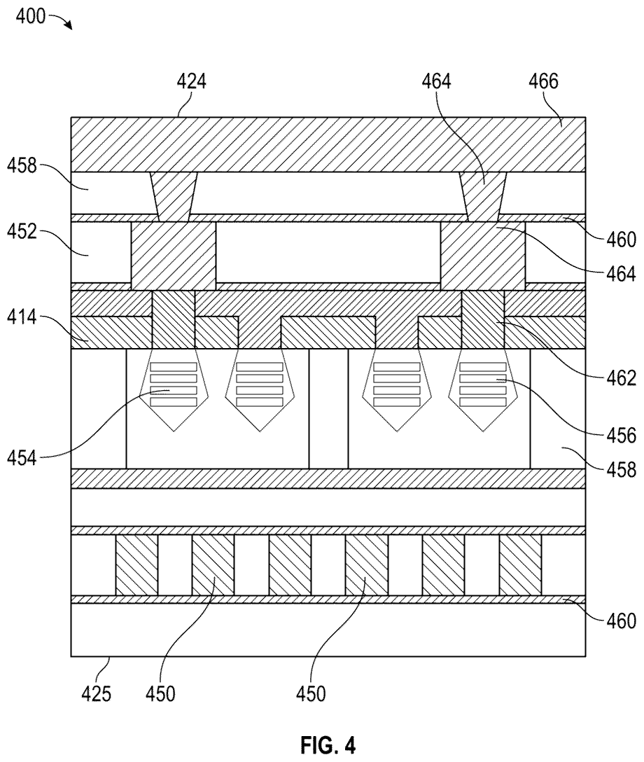

FIG. 4 illustrates a device 400. The device 400 may be used in place of the substrate 114 described with regard to FIGS. 1A-2. The device 400 includes an upper surface 424, a bottom surface 425, frontside signal lines 450, a substrate 414, a backside isolation layer 452, a device voltage (Vdd 454), a series voltage (Vss 456), a plurality of dielectric layers 458, a plurality of isolation layers 460, a backside contact 462, a plurality of contacts 464, and a contact layer 466. The backside isolation layer 452 is disposed over the substrate 414. The backside isolation layer 452 is in contact with the Vdd 454 and Vss 456 via trenches in the substrate 414.

The dielectric layers 458, the isolations layers 460, and the backside isolation layer 452 includes silicon oxides and silicon nitrides, both undoped or doped with carbon, or a combination thereof. The dielectric layers 458, isolation layers 460, and backside isolation layers 452 function as electrical insulation between the plurality of contacts 464 and the contact layer 466.

The backside contact 462 includes tungsten, molybdenum, titanium, cobalt, nickel, or a combination thereof. The backside contact 462 is disposed through the backside isolation layer 452 and the substrate 414. The backside contact 462 connects the Vdd 454 and the Vss 456 to the plurality of contacts 464. The connection (e.g., a metal to to semiconductor contact) between the backside contact 462 and the Vdd 454 and Vss 456 is promoted using a dopant. The dopant is implanted in or deposited on the Vdd 454 and Vss 456.

The Vss 456 and Vdd 454 include silicon germanium (SiGe), phosphorus doped silicon, or a combination thereof. The germanium content in the SiGe ranges from about 5% to about 80%. The Vdd provides an internal working voltage of the device 400. The Vss provides a voltage of a common ground terminal of the device 400.

The plurality of contacts 464 and the contact layer 466 include copper, molybdenum, cobalt, tungsten, or a combination thereof. The plurality of contacts 464 and the contact layer 466 provide the electrical wiring to connect outside terminals for voltage and current.

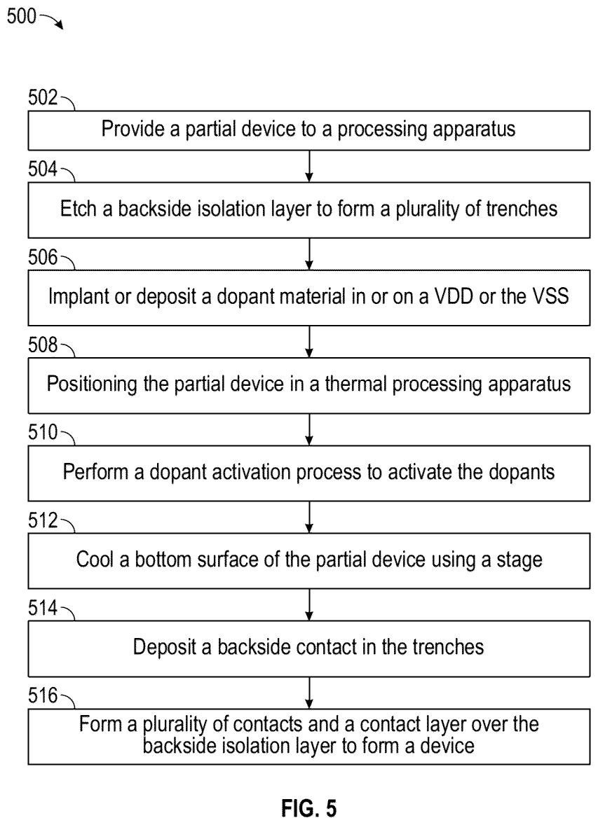

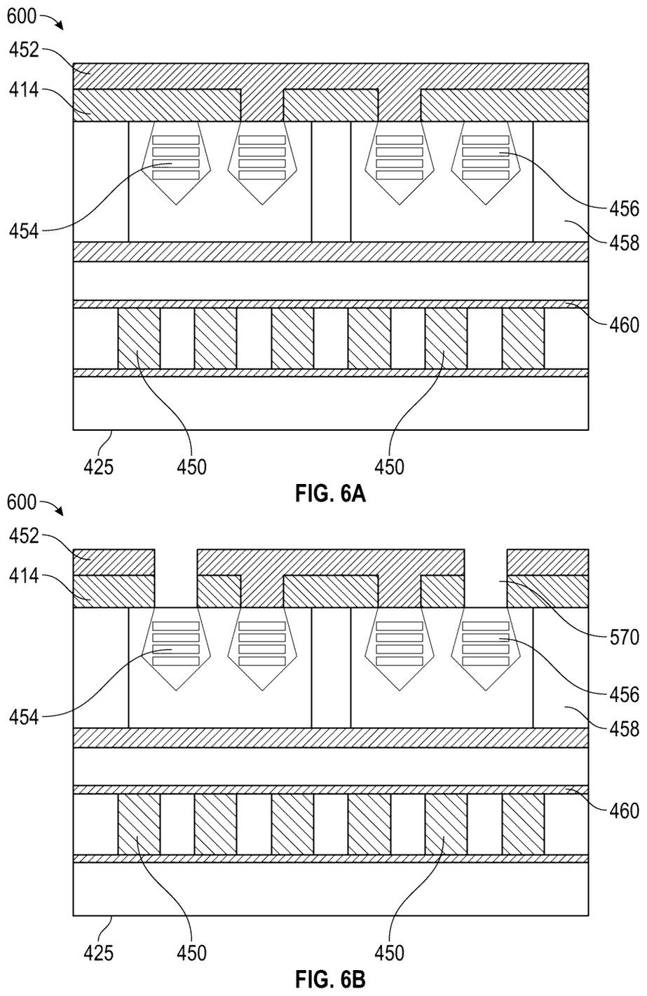

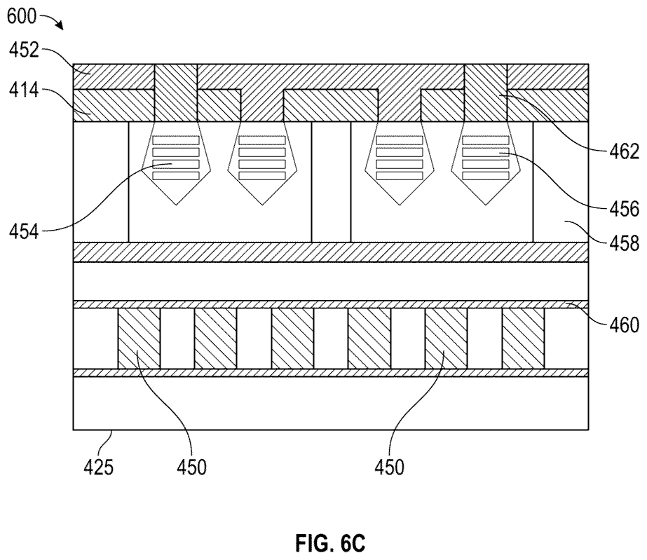

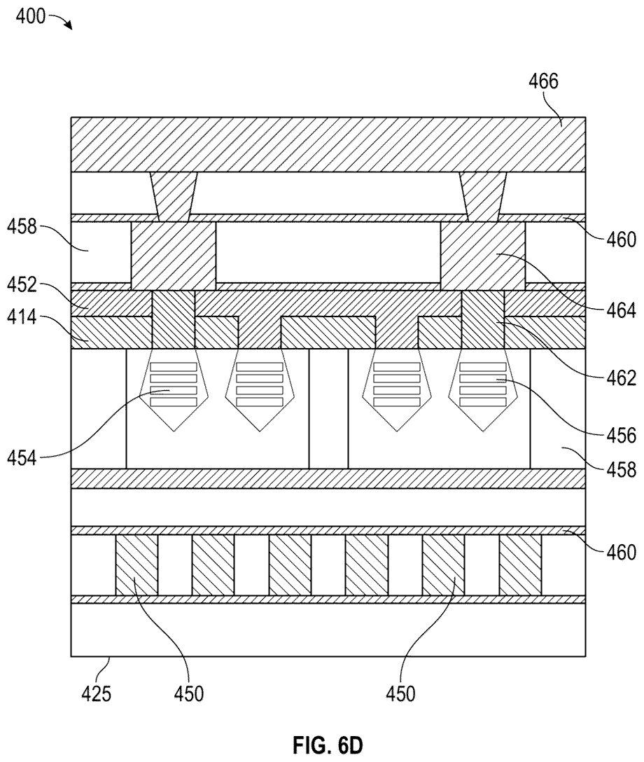

FIG. 5 illustrates a flow diagram of a method 500 of forming a device 400. FIG. 6A-6D illustrate schematic, cross-section views of a portion of the device 400 during the method 500. At operation 502, a partial device 600, as shown in FIG. 6A, is provided to a processing apparatus. The processing apparatus may include a chemical vapor deposition (CVD) chamber, a plasma vapor deposition (PVD) chamber, atomic layer deposition (ALD) chamber, or other similar processing chamber. The partial device 600 includes frontside signal lines 450, a substrate 414, a backside isolation layer 452, a device voltage (Vdd 454), a series voltage (Vss 456), a plurality of dielectric layers 458, and a plurality of isolation layers 460.

At operation 504, as shown in FIG. 6B, the backside isolation layer 452 is etched to form a plurality of trenches 570. The trenches enable access to the Vdd 454 and the Vss 456.

At operation 506, a dopant material is implanted or deposited in or on the Vss and Vdd. The dopant material may be deposited on the Vdd 454 and Vss 456 using epitaxial deposition or may be implanted onto the Vdd 454 and Vss 456. The dopant material includes boron, phosphorus, gallium, antimony, or combinations thereof.

At operation 508, the partial device 600 is positioned in the thermal processing apparatus. The thermal processing apparatus may be the apparatus 100 or the apparatus 200. A bottom surface 425 of the partial device 600 is disposed on a stage 116 in the thermal processing apparatus (e.g., apparatus 100 or apparatus 200). At operation 510, a dopant activation is performed to activate the dopants. The dopant activation is performed using an anneal process, for example a dynamic surface anneal (DSA) process. The DSA process includes rapid high temperature anneal pulses on the dopant material implanted in or deposited on the Vdd 454 and Vss 456. In some embodiments, the dopant activation is performed subsequent to the deposition of the backside contact 462, as shown in operation 512.

At operation 512, a bottom surface 425 of the device 400 is cooled by the stage 116. The stage 116 includes one or more channels 130 through which a working fluid may flow. The working fluid allows for a bottom surface 425 of the substrate 114 disposed upon the stage 116 to be cooled, by conduction, to a lower temperature during the thermal processing (e.g., the DSA processing). The stage 116 enables an increased in the temperature gradient along the depth of the device 400. The increase in the temperature gradient along the depth of the device 400 reduces the thermal budget expenditure of frontside signal line 450 deposited closer to the bottom surface 425 of the substrate 114.

At operation 514, as shown in FIG. 6C, the backside contact 462 is deposited. The activation of the dopants promotes the formation of a metal to semiconductor contact. In particular, the activation of the dopants promotes the formation of the contact between the backside contact and the Vdd 454 and the Vss 456 by reducing a Fermi energy barrier between the backside contact and the Vdd 454 and Vss 456.

At operation 516, as shown in FIG. 6D, a plurality of contacts 464 and a contact layer 466 is formed over the backside isolation layer 452 to form the device 400. The plurality of contacts 464 are formed in one or more dielectric layers 458 and isolation layer 460 disposed over the backside isolation layer 452. The plurality of contacts 464 form a connection between the contact layer 466 and the backside contact 462.

In summary, a thermal processing apparatus includes a substrate support configured to receive a substrate thereon. The substrate support includes one or more channels configured to flow a working fluid therethrough. The working fluid is configured to enable a bottom surface of the substrate disposed upon the substrate support to be cooled to a temperature of about 200° C. to about −200° C. during the annealing process. The substrate support enables an increase in the temperature gradient along the depth of the substrate. The increase in the temperature gradient along the depth of the substrate reduces the thermal budget expenditure of a structure deposited closer to the bottom surface of the substrate. Meanwhile, the upper surface of the substrate may still be processed at the higher temperatures (e.g., about 500° C. to about 1200° C.) required to perform dopant activation, film densification, annealing, or other applications.

Implementations and all of the functional operations described in this specification can be implemented in digital electronic circuitry, or in computer software, firmware, or hardware, including the structural means disclosed in this specification and structural equivalents thereof, or in combinations of them. Implementations described herein can be implemented as one or more non-transitory computer program products, i.e., one or more computer programs tangibly embodied in a machine readable storage device, for execution by, or to control the operation of, data processing apparatus, e.g., a programmable processor, a computer, or multiple processors or computers.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them. Processors suitable for the execution of a computer program include, by way of example, both general and special purpose microprocessors, and any one or more processors of any kind of digital computer.

Computer readable media suitable for storing computer program instructions and data include all forms of nonvolatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

The term “comprises” and grammatical equivalents thereof are used herein to mean that other components, ingredients, operations, etc. are optionally present. For example, an article “comprising” (or “which comprises”) components A, B, and C can consist of (i.e., contain only) components A, B, and C, or can contain not only components A, B, and C but also one or more other components. In addition, whenever a composition, an element or a group of elements is preceded with the transitional phrase “comprising” or grammatical equivalents thereof, it is understood that it is contemplated that the same composition or group of elements may be preceded with transitional phrases “consisting essentially of,” “consisting of,” “selected from the group of consisting of,” or “is” preceding the recitation of the composition, element, or elements and vice versa.

Where reference is made herein to a method comprising two or more defined operations, the defined operations can be carried out in any order or simultaneously (except where the context excludes that possibility), and the method can include one or more other operations which are carried out before any of the defined operations, between two of the defined operations, or after all of the defined operations (except where the context excludes that possibility).

When introducing elements of the present disclosure or exemplary aspects or implementation(s) thereof, the articles “a,” “an,” “the” and “said” are intended to mean that there are one or more of the elements.

The terms “comprising,” “including” and “having” are intended to be inclusive and mean that there may be additional elements other than the listed elements.

While the foregoing is directed to implementations of the present disclosure, other and further implementations of the disclosure may be devised without departing from the basic scope thereof, and the scope thereof is determined by the claims that follow.

What is claimed is:

1. A thermal processing apparatus, comprising:
a radiation module configured to generate a line of radiation for an annealing process;
a substrate support configured to receive a substrate thereon, the substrate support comprising:
one or more channels configured to flow a working fluid therethrough, wherein the working fluid is configured to enable a bottom surface of the substrate disposed upon the substrate support to be cooled to a temperature of about 200° C. to about −200° C. during the annealing process; and
a translation mechanism configured to translate the substrate support and the line of radiation relative to one another.

2. The thermal processing apparatus of claim 1, wherein the line of radiation is a plurality of rapid high temperature anneal pulses, the rapid high temperature anneal pulses are generated for a period of about 0.05 milliseconds to about 5 milliseconds.

3. The thermal processing apparatus of claim 1, further comprising a controller, the controller storing instructions causing the radiation module to heat an upper surface of the substrate to a temperature of about 800° C. to about 1,300° C. by the line of radiation.

4. The thermal processing apparatus of claim 1, further comprising a controller, the controller storing instructions causing the radiation module to heat an upper surface of the substrate, wherein a temperature gradient from the upper surface of the substrate to the temperature at the bottom surface of the substrate is about 300° C. to about 1400° C.

5. The thermal processing apparatus of claim 1, wherein the radiation module comprises a plurality of laser diodes, wherein each laser diodes of the plurality of laser diodes has a power of about 0.5 KW to about 50 kW.

6. The thermal processing apparatus of claim 1, wherein the radiation line has a power density from about 10 KW/cm² to about 200 kW/cm².

7. The thermal processing apparatus of claim 1, wherein the radiation module produces radiation having a wavelength from about 190 nm to about 950 nm.

8. A device, comprising:
a substrate;
a backside isolation layer disposed over the substrate;
a backside contact formed through the backside isolation layer and the substrate;
a device voltage in contact with the backside isolation layer and the backside contact;
a series voltage in contact with the backside isolation layer and the backside contact;
a frontside signal line disposed between a bottom surface of the device and the device voltage and the series voltage;
a dopant disposed on or implanted in the device voltage and the series voltage, wherein the dopant is an activated dopant configured to promote a formation of a metal to semiconductor contact; and
wherein the dopant is activated using an annealing process, and wherein the device is disposed on a substrate support during the annealing process, the substrate support being configured to cool a bottom surface of the device to a temperature of about 200° C. to about −200° C. during the annealing process.

9. The device of claim 8, wherein the dopant includes boron, phosphorus, gallium, antimony, or combinations thereof.

10. The device of claim 8, wherein the backside contact includes tungsten, molybdenum, titanium, cobalt, nickel, or a combination thereof.

11. The device of claim 8, wherein the annealing process includes a plurality of rapid high temperature anneal pulses, the rapid high temperature anneal pulses are generated for a period of about 0.05 milliseconds to about 5 milliseconds.

12. The device of claim 8, wherein an upper surface of the substrate is heated to a temperature of about 800° C. to about 1,300° C. during the annealing process.

13. The device of claim 8, wherein a temperature gradient from an upper surface of the substrate to the temperature at the bottom surface of the substrate is about 300° C. to about 1400° C.

14. The device of claim 8, wherein the annealing process is performed by a radiation source, wherein the radiation source produces radiation having a wavelength from about 190 nm to about 950 nm.

15. A method of processing a device, comprising:
etching a backside isolation layer of a partial device to form a plurality of trenches to expose a device voltage (Vdd) and a series voltage (Vss);
depositing a dopant material on the Vdd and the Vss;
positioning a partial device in a thermal processing apparatus, wherein the partial device is disposed on a stage of the thermal processing apparatus;
performing a dopant activation process to activate the dopant material;
cooling a bottom surface of the partial device using the stage, wherein the bottom surface of the partial device is at a temperature of about 200° C. to about −200° C. during the dopant activation; and
depositing a backside contact in the trenches.

16. The method of claim 15, wherein the dopant activation process is an annealing process.

17. The method of claim 16, wherein the annealing process includes a plurality of rapid high temperature anneal pulses, the rapid high temperature anneal pulses are generated for a period of about 0.05 milliseconds to about 5 milliseconds.

18. The method of claim 15, wherein an upper surface of the partial device is heated to a temperature of about 800° C. to about 1,300° C. during the dopant activation.

19. The method of claim 18, wherein a temperature gradient from an upper surface of the partial device to the bottom surface of the partial device is about 300° C. to about 1400° C.

20. The method of claim 15, wherein the dopant activation is performed by a radiation source, wherein the radiation source produces radiation having a wavelength from about 190 nm to about 950 nm.
